(19) United States
(12) Patent Application Publication
(10) Pub. No.: US 2026/0309653 A1
(43) Pub. Date: Oct. 8, 2026

(54) SAMPLE PREPARATION SYSTEM FOR ELECTRON MICROSCOPY

(71) Applicant: THE REGENTS OF THE UNIVERSITY OF CALIFORNIA, Oakland, CA (US)

(72) Inventors: David MILSTED, Berkeley, CA (US); Tara MISHRA, Albany, CA (US); Gerbrand CEDER, Orinda, CA (US)

(21) Appl. No.: 19/531,787

(22) Filed: Feb. 6, 2026

Related U.S. Application Data
(60) Provisional application No. 63/785,106, filed on Apr. 8, 2025.

(51) Int. Cl. G01N 23/2204; G01N 23/2202; G01N 23/2251; H01J 37/26; H01J 37/28

(52) U.S. Cl. CPC G01N 23/2204; G01N 23/2202; G01N 23/2251; H01J 37/261; H01J 37/28; G01N 2223/102; G01N 2223/309; G01N 2223/312; G01N 2223/351

(57) ABSTRACT

This disclosure provides systems, methods, and apparatus related to electron microscopy sample preparation. In one aspect, a system includes a first sample holder tray operable to hold electron microscopy (EM) sample holders, a sample holder handling apparatus including a sample holder mechanism, and a sample exposing apparatus. The sample exposing apparatus includes a platform, an electrode, and a high voltage power supply. The high voltage power supply is operable to apply a voltage to the electrode and an EM sample holder or a second electrode positioned proximate the EM sample holder. The voltage is operable to attract a powder sample disposed on the platform to the EM sample holder. The sample holder handling apparatus is operable to transfer the EM sample holder between the first sample holder tray and the sample exposing apparatus.

### RELATED APPLICATIONS

This application claims priority to U.S. Provisional Patent Application No. 63/785,106, filed 8 Apr. 2025, which is hereby incorporated by reference.

### STATEMENT OF GOVERNMENT SUPPORT

This invention was made with government support under Contract No. DE-AC02-05CH11231 awarded by the U.S. Department of Energy. The government has certain rights in this invention.

### BACKGROUND

Computational and high-throughput materials investigations have paved the way for accelerated discovery and prediction of materials with unique properties. The experimental realization of these predicted materials, aimed at increasing experimental throughput, has been advanced by the development of self-driving laboratories (SDLs). Driven by high-performance computing, customizable hardware development, and machine learning, SDLs hold great promise in augmenting efficiency in experimental protocols. Additionally, SDLs have promoted the reproducibility and digitization of research in experimental materials. While SDLs have successfully automated the synthesis of thin films, solution-based synthesis, nanoparticle synthesis, and solid-state materials, advanced material characterization remains an important component for determining experimental outcomes and providing feedback to these systems.

To address this, researchers have made substantial progress in automating various characterization techniques, both within and outside the SDL framework. These advances include optical and electron microscopy, X-ray diffraction, and even the automation of experiments at large-scale facilities such as synchrotrons. Parallel developments in autonomous algorithms have improved the analysis of complex datasets obtained from electron microscopy and X-ray diffraction. The advent of benchtop scanning electron microscopes (SEMs) has broadened access to morphology and compositional characterization of novel materials at the micron scale within SDLs. Further, integrating data from electron microscopy with other techniques, such as X-ray diffraction, can provide insights for autonomous algorithms, enhancing the capabilities of SDLs.

Despite these advancements, integrating advanced characterization techniques, particularly electron microscopy, continues to present significant challenges. One obstacle is the lack of reproducible and automated sample preparation methods. This issue is especially pronounced in research and development environments, where sample preparation platforms must accommodate diverse material systems while maintaining sufficient adaptability for integration into existing characterization instruments without degrading the integrity of the samples.

Traditional scanning electron microscopy (SEM) sample preparation of inorganic materials typically involves drop-casting a small amount of powder onto a stub covered with carbon or copper tape, followed by removing excess material using an air blower or by gently tapping the stub on a hard surface. These steps require precise and delicate manual manipulation of very small quantities of material, making them difficult to replicate with robotic systems. Additionally, manual drop-casting can lead to significant particle agglomeration, especially with challenging samples, which complicates downstream autonomous analysis such as particle size determination. These limitations hinder the reliable integration of SEM sample preparation into SDL ecosystems.

Manual transmission electron microscopy (TEM) sample preparation presents its own challenges, typically requiring particles of less than 100 nanometer (nm) in thickness. Achieving this often involves mechanically grinding powder samples, dissolving them in a non-reactive solvent, sonication, and subsequent dispersion onto a TEM grid. Although these procedures can yield suitably sized particles for characterization, they are labor-intensive and involve complex manual steps that are difficult to automate. While some progress has been made in automating TEM sample preparation, such as using focused ion beam (FIB) technology or automating the preparation of biological specimens, automated procedures for preparing inorganic powder samples remain lacking.

### SUMMARY

Embodiments described herein automate particle transfer without solvent onto scanning electron microscopy (SEM) stubs and transmission electron microscopy (TEM) grids. Embodiments described herein include applying a static voltage to or nearby an electron microscopy sample holder to create an electric field which attracts particles from a container and attaches the particles to the sample holder.

One innovative aspect of the subject matter described in this disclosure can be implemented in an apparatus including a first sample holder tray operable to hold electron microscopy (EM) sample holders, a sample holder handling apparatus including a sample holder mechanism, and a sample exposing apparatus. The sample exposing apparatus includes a platform, an electrode, and a high voltage power supply. The high voltage power supply is operable to apply a voltage to the electrode and an EM sample holder or a second electrode positioned proximate the EM sample holder. The voltage is operable to attract a powder sample disposed on the platform to the EM sample holder. The sample holder handling apparatus is operable to transfer the EM sample holder between the first sample holder tray and the sample exposing apparatus.

Another innovative aspect of the subject matter described in this disclosure can be implemented in a system including a first sample holder tray operable to hold scanning electron microscopy (SEM) stubs, a second sample holder tray operable to hold transmission electron microscopy (TEM) grids, a sample holder handling apparatus, and a sample exposing apparatus. The sample holder handling apparatus includes a vacuum pump, a SEM needle, and a TEM needle. The SEM needle comprises a first hollow cylinder operable to hold a SEM stub when a vacuum is applied to the first hollow cylinder with the vacuum pump. The TEM needle comprises a second hollow cylinder operable to hold a TEM grid when a vacuum is applied to the second hollow cylinder with the vacuum pump. The sample exposing apparatus includes a platform comprising a flat surface, an electrode, and a high voltage power supply. The high voltage power supply is operable to apply a voltage to the electrode and the SEM stub or the electrode and a second electrode positioned proximate the TEM grid. The voltage is operable to attract a powder sample disposed on the platform to the SEM stub or the TEM grid. The sample holder handling apparatus is operable to transfer the SEM stub or the TEM grid to and from the first sample holder tray or the second sample holder tray, respectively, and the sample exposing apparatus.

Details of one or more embodiments of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A shows an example of a schematic illustrations of a system for preparing a powder sample for electron microscopy. FIG. 1B shows an example of a top-down schematic illustrations of a system for preparing a powder sample for electron microscopy.

FIG. 1C shows an example of a schematic illustration of a sample holder mechanism.

FIG. 1D shows an example of a schematic illustration of a sample exposing apparatus for use when the EM sample holder is an SEM stub.

FIG. 1E shows an example of a schematic illustration of a sample exposing apparatus for use when the EM sample holder is an TEM grid.

FIG. 2 shows a flow chart depicting the operation algorithm of the EMSBot.

FIGS. 3A-3D show the results of a statistical analysis of the size of the particles prepared using the EMSBot from SEM micrographs. FIG. 3A shows the convention of distance parameter followed during the exposition of the SEM stub/TEM grid. Typical SEM micrographs used for statistical analysis of the particle sizes were prepared from a distance of (FIG. 3B) −15 mm and (FIG. 3C) −20 mm from the top of the crucible rim. FIG. 3D shows a histogram analysis of the particle size as a function of the stub distance from the top of the crucible, and a magnified histogram of the distribution of the particles>25 μm.

FIGS. 4A-4D show representative SEM images and corresponding segmentation masks used for particle size distribution analysis. Samples were prepared using the EMSBot (FIGS. 4A and 4B) and manual methods (FIGS. 4C and 4D), with the examples depicting medium-sized particles (8-50 μm diameter). Left panels show SEM images with overlaid circles and identification numbers indicating particles detected by the automated program. Right panels display the associated masks generated by image segmentation. The bar denotes a scale of 50 μm.

FIGS. 5A and 5B show typical STEM-HAADF micrographs at different magnifications from a TEM grid prepared using the EMSBot sample preparation robot. FIG. 5A shows a low-magnification micrograph. FIG. 5B shows a high-magnification view of a representative particle.

FIGS. 6A-6I show SEM micrographs of various chemical compounds and powder mixtures prepared using the EMSBot. The bar denotes a scale of 50 μm.

FIGS. 7A and 7B show examples of schematic illustrations of an SEM stub.

FIGS. 8A and 8B show examples of schematic illustrations of a holey carbon film disposed on an electron microscopy grid

### DETAILED DESCRIPTION

Reference will now be made in detail to some specific examples of the invention including the best modes contemplated by the inventors for carrying out the invention. Examples of these specific embodiments are illustrated in the accompanying drawings. While the invention is described in conjunction with these specific embodiments, it will be understood that it is not intended to limit the invention to the described embodiments. On the contrary, it is intended to cover alternatives, modifications, and equivalents as may be included within the spirit and scope of the invention as defined by the appended claims.

In the following description, numerous specific details are set forth in order to provide a thorough understanding of the present invention. Particular example embodiments of the present invention may be implemented without some or all of these specific details. In other instances, well known process operations have not been described in detail in order not to unnecessarily obscure the present invention.

Various techniques and mechanisms of the present invention will sometimes be described in singular form for clarity. However, it should be noted that some embodiments include multiple iterations of a technique or multiple instantiations of a mechanism unless noted otherwise.

The terms “about” or “approximate” and the like are synonymous and are used to indicate that the value modified by the term has an understood range associated with it, where the range can be ±20%, ±15%, ±10%, ±5%, or ±1%. The terms “substantially” and the like are used to indicate that a value is close to a targeted value, where close can mean, for example, the value is within 80% of the targeted value, within 85% of the targeted value, within 90% of the targeted value, within 95% of the targeted value, or within 99% of the targeted value.

There is a need for modular, automated systems capable of preparing powder samples for both SEM and TEM, thereby facilitating material characterization within SDL workflows. The application of static electricity can induce opposite charges on the surface of a material. Using this concept of charge induction, particles of a sample can be attracted to an SEM stub or an TEM grid. In some embodiments, a modular device is used to perform the method. Such a modular device can be integrated with an autonomous laboratory or an SDL.

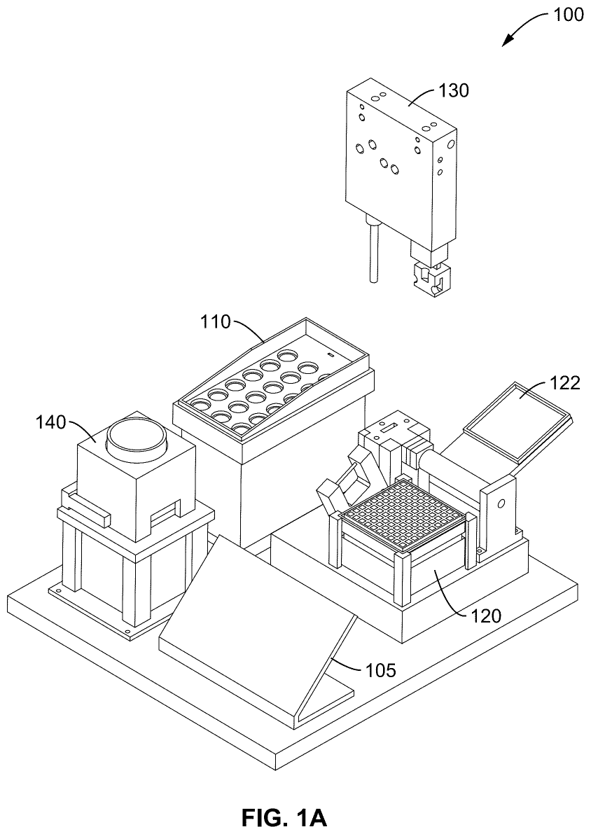

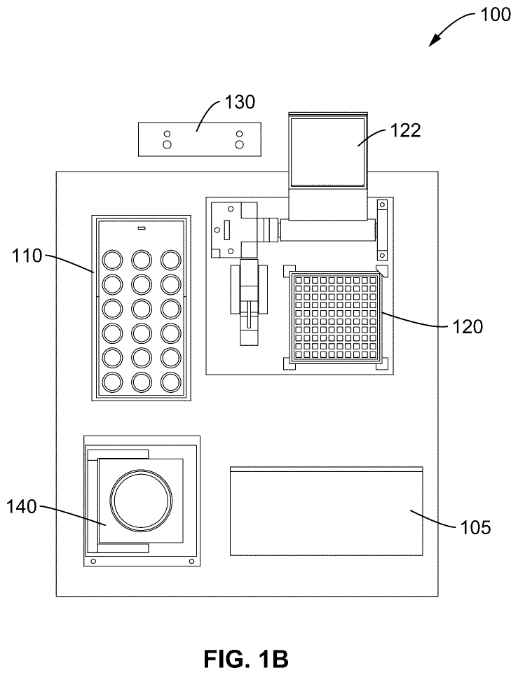

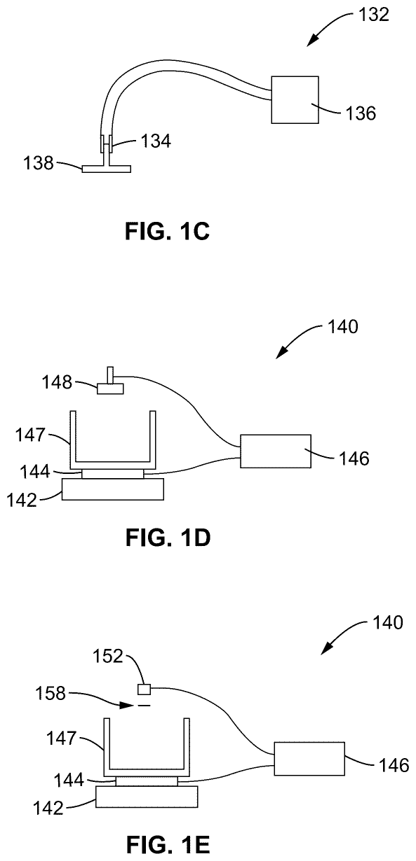

FIG. 1A shows an example of a schematic illustration of a system for preparing a powder sample for electron microscopy. FIG. 1B shows an example of a top-down schematic illustration of a system for preparing a powder sample for electron microscopy.

As shown in FIGS. 1A and 1B, a system 100 for preparing a powder sample for electron microscopy includes a first sample holder tray 110, a sample holder handling apparatus 130, and a sample exposing apparatus 140.

The first sample holder tray 110 is operable to hold electron microscopy (EM) sample holders. In some embodiments, the EM sample holders are scanning electron microscopy (SEM) stubs. The first sample holder tray 110 shown in FIGS. 1A and 1B would hold SEM stubs. In some embodiments, the EM sample holders are transmission electron microscopy (TEM) grids.

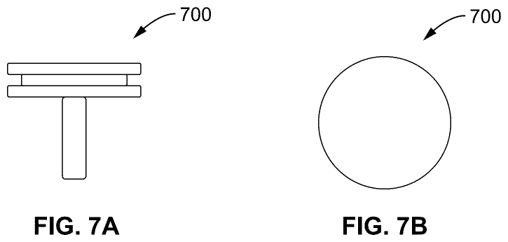

An SEM stub is a conductive sample holder. Different SEM stubs are used in SEMs made by different manufacturers. In some embodiments, an SEM stub comprises a disk with a post on one side of the disk at the center of the disk (i.e., a pin stub). FIGS. 7A and 7B show examples of schematic illustrations of an SEM stub. FIG. 7A shows an example of a side view illustration of an SEM stub 700. FIG. 7B shows an example a top-down view illustration of the SEM stub 700.

An SEM stub is a mounting platform used to hold a sample inside an SEM. An SEM stub is typically metal (e.g., aluminum) and has dimensions of about 1 centimeter (cm) (i.e., an SEM stub generally has a height of about 1 cm and a face onto which a sample is attached has a dimension (e.g., a dimeter) of about 1 cm). The sample is attached to the flat top of the SEM stub using conductive adhesive, tape, or paste to ensure mechanical stability and electrical conductivity. A mounting pin attached to the base of the SEM stub secures the stub into an SEM stage, providing proper alignment and electrical grounding. The SEM stub allows positioning of the specimen in the SEM chamber and helps minimize charging effects during electron imaging.

An TEM grid can be made of a number of materials or a combination or alloy of such materials. In some embodiments, an TEM grid comprises gold, molybdenum, titanium, or copper. In some embodiments, an TEM grid is an about 3 millimeter (mm) diameter disc (e.g., 3.05 mm diameter) that has a thickness and mesh size ranging from about 3 microns to 100 microns. In some embodiments, an TEM grid has a thickness of about 30 microns and a mesh size of about 100 microns.

In some embodiments, an TEM grid comprises a first surface and a second surface, and the first surface of the electron microscopy grid has a carbon film disposed thereon. In some embodiments, the carbon film has a thickness of about 10 nanometers (nm) to 25 nm, or about 12 nm.

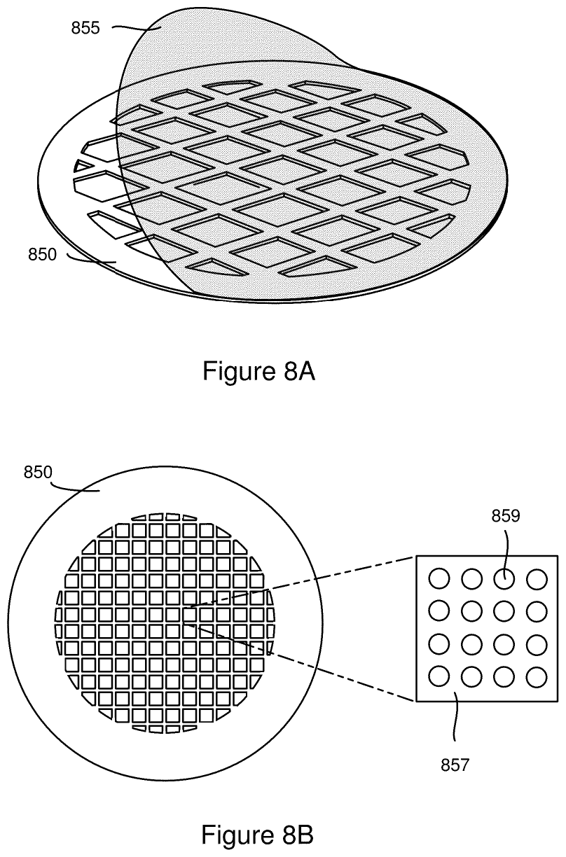

FIGS. 8A and 8B show examples of schematic illustrations of a holey carbon film disposed on an electron microscopy grid. As shown in FIG. 8A, in some embodiments, an TEM grid 850 has a holey carbon film disposed on one side of the TEM grid 850. FIG. 8B shows the holey carbon film 855 disposed over one opening in the mesh 857 of the TEM grid 850. The holey carbon film has holes 859 defined in the carbon film.

In some embodiments, the sample exposing apparatus 140 includes a platform, an electrode, and a high voltage power supply. The high voltage power supply is operable to apply a voltage to the electrode and an EM sample holder (e.g., when the EM sample holder is an SEM stub) or second electrode positioned proximate the EM sample holder (e.g., when the EM sample holder is an TEM grid). The voltage attracts a powder sample disposed on the platform to the EM sample holder.

In some embodiments, the sample holder handling apparatus 130 includes a sample holder mechanism. In some embodiments, the sample holder handling apparatus 130 is operable to transfer the EM sample holder to and from the first sample holder tray 110 and the sample exposing apparatus 140.

In some embodiments, the sample holder mechanism comprises a tweezer-like mechanism operable to hold an EM sample holder. Such a sample holder mechanism can be used to pick up and transfer a SEM stub, for example. In some embodiments, the sample holder mechanism comprises a vacuum pump and an EM needle. The EM needle comprises a hollow cylinder operable to hold an EM sample holder when a vacuum is applied to the hollow cylinder with the vacuum pump. In some embodiments, an SEM needle comprises a metal (e.g., stainless steel). In some embodiments, an TEM needle comprises a polymer (e.g., polytetrafluoroethylene). Such a sample holder mechanism can be used to pick up and transfer an SEM stub or an TEM grid, for example.

FIG. 1C shows an example of a schematic illustration of a sample holder mechanism. The sample holder mechanism 132 shown in FIG. 1C includes an EM needle 134 and a vacuum pump 136. As shown in FIG. 1C, the sample holder mechanism is holding an SEM stub 138 with a vacuum being applied to the EM needle 134.

In some embodiments, the system includes a sensor operable to sense when the sample holder handling apparatus 130 picks up the EM sample holder. In some embodiments, the sensor comprises a laser sensor (not shown). In some embodiments, the sensor comprises an infra-red light sensor (not shown) or a visible light sensor (not shown).

For the sample exposing apparatus, in some embodiments, the electrode is positioned under the platform. In some embodiments, the electrode is positioned on an upper surface of the platform. In some embodiments, the platform comprises a flat surface. In some embodiments, the platform comprises an electrically insulating material. For example, in some embodiments, the platform comprises polypropylene. In some embodiments, the polypropylene is about 3 millimeters (mm) to 5 mm thick.

In some embodiments, when the EM sample holders are SEM stubs, the voltage is applied to the electrode and the SEM stub. In some embodiments, the voltage applied to the electrode and the SEM stub is about 100 V to 50 kV. In some embodiments, the voltage is applied to the electrode and the SEM stub for about 0.1 seconds to 5 minutes. For example, in some embodiments, the voltage applied to the electrode and the SEM stub is about 10 kV for about 5 seconds. In some embodiments, a distance between the platform and the SEM stub when the voltage is applied to the electrode and the SEM stub is about 1 mm to 50 mm, or about 15 mm to 20 mm.

FIG. 1D shows an example of a schematic illustration of a sample exposing apparatus for use when the EM sample holder is an SEM stub. As shown in FIG. 1D, the sample exposing apparatus 140 includes a platform 142, an electrode 144, a high voltage power supply 146, and a container 147 operable to hold a powder sample. In some embodiments, the electrode 144 is positioned on an upper surface of the platform 142. In some embodiments, the container 147 contacts the electrode 144 when the container 147 is sitting on the platform 142. In some other embodiments, the electrode 144 is positioned under the platform 142. In some embodiments, the electrode 144 is proximate or in contact with the platform 142. The high voltage power supply 146 is in electrical contact with an SEM stub 148 and the electrode 144.

In some embodiments, when the EM sample holders are TEM grids, the voltage is applied to the electrode and the second electrode positioned proximate the TEM grid, with the TEM grid being positioned between the platform and the second electrode. In some embodiments, the voltage applied to the electrode and the second electrode is about 100 V to 50 kV. In some embodiments, voltage is applied to the electrode and the second electrode for about 0.1 seconds to 5 minutes. For example, in some embodiments, the voltage applied to the electrode and the TEM grid is about 10 kV for about 5 seconds. In some embodiments, a distance between the platform and the TEM grid when the voltage is applied to the electrode and the second electrode is about 1 mm to 50 mm, or about 8 mm. In some embodiments, the TEM grid is positioned at a distance from the second electrode such that the TEM grid is electrically isolated from the second electrode (i.e., when a voltage is applied to the electrode and the second electrode). In some embodiments, the second electrode is positioned about 2 mm to 4 mm, or about 3 mm, from a face of the TEM grid.

FIG. 1E shows an example of a schematic illustration of a sample exposing apparatus for use when the EM sample holder is an TEM grid. As shown in FIG. 1E the sample exposing apparatus 140 includes a platform 142, an electrode 144, a second electrode 152, a high voltage power supply 146, and a container 147 operable to hold a powder sample. In some embodiments, the electrode 144 is positioned on an upper surface of the platform 142. In some embodiments, the container 147 contacts the electrode 144 when the container 147 is sitting on the platform 142. In some other embodiments, the electrode 144 is positioned under the platform 142. In some embodiments, the electrode 144 is proximate or in contact with the platform 142. The high voltage power supply 146 is in electrical contact with the second electrode 154 and the electrode 146. A TEM grid 158 is positioned between the platform 142 and the second electrode 154.

The (1) voltage applied to the SEM stub/nearby the TEM grid, (2) the distance between the powder and the SEM stub/TEM grid, (3) the period of time for which the voltage is applied, and (4) the properties of the voltage (e.g., magnitude, current, and frequency) applied to the SEM stub/nearby the TEM grid, in part control the amount and the sizes of the particles that are transferred to the SEM stub/TEM grid. Additionally, due to the electric fields associated with the SEM sample preparation, elongated particles tend to stick vertically to an SEM stub.

In some embodiments, the system 100 includes a second sample holder tray 120. The second sample holder tray 120 shown in FIGS. 1A and 1B would hold TEM grids. In some embodiments, the first sample holder tray 110 is operable to hold SEM stubs and the second sample holder tray 120 is operable to hold TEM grids.

In some embodiments, when the EM sample holders are TEM grids, the system further comprises a cover 122 for the second sample holder tray 120 (i.e., the sample holder tray of the system 100 operable to hold TEM grids). In some embodiments, each of the second sample holder tray 120 and the cover 122 include magnets (not shown). The magnets serve as a clamping mechanism for the cover 122 on the second sample holder tray 120.

When the system 100 includes both a sample holder tray for SEM stubs and a sample holder tray for TEM grids, the system includes the apparatus and devices to transfer a powder sample to an SEM stub and a TEM grid. Such apparatus and devices include one or two sample holder apparatus 130 (including sample holder mechanisms for SEM stubs and for TEM grids) and a second electrode 154 as part of the sample exposing apparatus 140. Such a system 100 is operable to prepare both SEM stubs and TEM grids.

The following examples are intended to be examples of the embodiments disclosed herein, and are not intended to be limiting.

A specific example of the system described above is the Electron Microscopy Sample Bot (EMSBot). The EMSBot is a solvent-free automated modular device designed specifically for electron microscopy powder sample preparation in SDLs. The EMSBot leverages static electricity principles, utilizing induced opposing charges between the powder particles and electron microscopy sample holders (SEM stubs or TEM grids) to achieve controlled particle deposition. This system offers unique advantages, including seamless integration with existing SDLs and the ability to facilitate individual user requests through a browser-based graphical user interface (GUI). Further, these features provide the versatility to prepare samples for both scanning electron microscopy (SEM) and transmission electron microscopy (TEM) within a single setup. Notably, the EMSBot generates a change in particle size dispersion based on operating conditions, allowing for the potential preferential deposition of smaller particles onto either TEM grids or SEM stubs. The EMSBot addresses the challenge of automated powder sample preparation, paving the way for the integration of advanced electron microscopy techniques into autonomous inorganic solid-state materials research workflows.

### EXAMPLE—Mechanical Design of the EMSBot

The EMSBot comprises two main components: a customized 3D printer and a control panel. The 3D printer is a modified commercial unit. All objects were designed using CAD software and printed with polylactic acid (PLA) filament. The original printer nozzle head was replaced with a custom “handling robot” designed to hold needles for picking up SEM stubs and TEM grids.

The printer bed was replaced with a 5 mm-thick polypropylene bed to provide electrical insulation. 3D-printed objects such as the SEM stub tray and TEM grid tray were assembled on this bed. The bot is equipped with a removable tray, allowing easy replacement to bring in clean stubs when necessary.

A laser sensor was installed to verify that the handling robot has picked up a SEM stub or a TEM grid for the exposition of the powder sample. The stepper motor uncovers the TEM grid tray by lifting the original TEM grid lid using a stainless steel sheet attached to the lid and a magnet attached to the pivoting cover. The lid in the TEM grid is important in preventing cross-contamination between the clean TEM grids and powder sample deposited grids.

On the polypropylene bed, a 3D-printed sample exposition station was assembled. This station is used to place the container containing the powder sample for deposition onto the SEM or TEM grids. An enclosure secures the sample container, allowing the electrode to touch the bottom of the container.

The handling bot comprises a vacuum system, controlled by the control panel, that includes two vacuum pumps connected to the SEM and TEM needles in the handling robot. This system enables the handling robot to pick up a SEM stub or a TEM grid for sample preparation for electron microscopy.

Particle deposition onto the SEM stub and TEM grids is based on electrostatic attraction. A high-voltage power supply (HVPS) provides the required voltage and current as specified by the control panel. The handling robot uses a vacuum pump to pick up the sample holders. The SEM electrode wire connects to the SEM needle, which attracts the sample powders. The TEM electrode is a live wire placed about 3 mm above the TEM grid, enhancing the electrical field strength above the grid. The TEM needle is made of plastic, with the electrode wire shaped to form a sharp point to attract the sample powders through the TEM grid.

### EXAMPLE—Experimental Testing of the EMSBot

To analyze the powder samples prepared using the EMSBot, SEM characterization using a benchtop SEM was performed. The SEM samples were prepared utilizing SEM stubs mounted with carbon tape. Powder samples were prepared using a constant electrostatic voltage of 10 kV and a current of 10 mA for 5 seconds. TEM samples were prepared using a standard 3.05 mm diameter formvar supported copper grids, with deposition parameters of 10 kV and 10 mA and 5 seconds of hold time. Scanning transmission electron microscope high-angle annular dark field (STEM-HAADF) characterization was performed using a microscope at the National Center for Electron Microscopy at the Molecular Foundry at Lawrence Berkeley National Laboratory.

### EXAMPLE—Sample Preparation Operation of the EMSBot

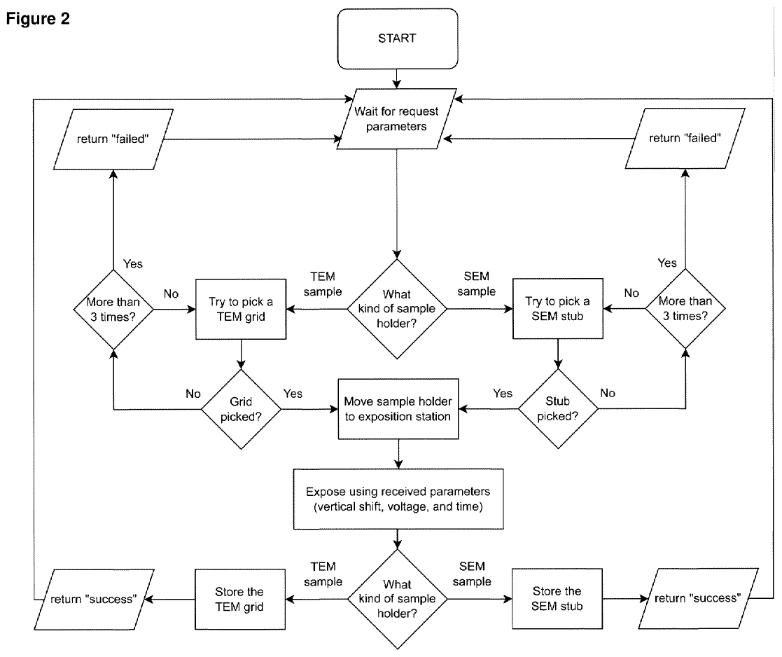

The sample preparation operations the EMSBot follows are shown in FIG. 2. The operation commands for the EMSBot can be provided either by the user or automatically by an operating system. The sample preparation procedure starts with a set of SEM stubs or TEM grid trays, and a container containing the powder is placed in the sample exposition station either by a robot or a user.

The instructions for sample preparation involve selecting if a SEM stub or if a TEM grid will be prepared, and then determining the distance of the SEM stub or TEM grid from the powder sample surface, setting the electric field voltage, and specifying the exposition time. The handling bot picks up the relevant stub or grid and verifies the success of the task using a laser sensor. If the bot fails to pick up the holder, it attempts the task three times before generating an error message that requires human assistance. Once the sample holder is successfully picked up, the handling bot transfers it to the exposition station, where powder samples are deposited onto the grid or stub using the electrostatic method according to the exposition parameters. After deposition, the SEM stub or TEM grid is returned to the sample storage area, and a success message is sent to the controller, indicating readiness for the next round of powder sample preparation.

### EXAMPLE—Experimental Verification of the Working of the EMSBot

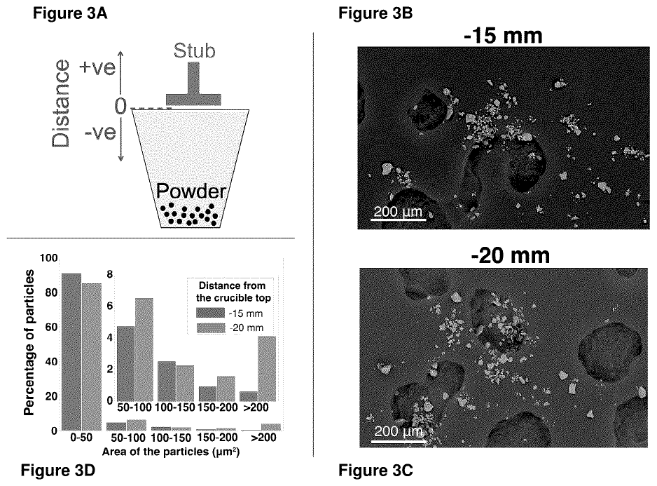

To evaluate the quality of the powder samples prepared by the EMSBot on SEM stubs and TEM grids, SEM and TEM characterization of these samples was performed. Given the possible variability of sample height within the crucible, the position of the SEM stub relative to the top rim of the crucible during sample transfer was measured, as shown schematically in FIG. 3A. FIGS. 3B and 3C show typical low magnification SEM micrographs of samples acquired by placing the SEM stub at 15 mm (FIGS. 3B) and 20 mm (FIG. 3C) below the top rim of the crucible, illustrating the dispersion of Al(OH)₃ particles transferred onto the SEM stub using the EMSBot.

The position of the stub with reference to the top rim of the crucible is a controllable parameter during the sample preparation using the EMSBot. Hence, it is interesting to note the effect of the stub position on the sizes of the collected particles. To statistically analyze the dispersion of particle sizes in the sample prepared using the EMSBot, multiple SEM micrographs at different stub positions were analyzed. The particles were identified in the SEM micrographs through a thresholding procedure followed by binarization. These binary maps were then used to calculate the area of each particle. This analysis was performed using software. The statistical distribution of particle areas at two positions, −15 mm and −20 mm from the top of the crucible on the SEM stub, is illustrated in the form of a histogram in FIG. 3D. A total of 314 and 868 particles over multiple stubs were statistically analyzed following the procedure above at these distances, respectively.

From the histogram distribution, it is observed that when the SEM stub is positioned further away from the powder surface (−15 mm from the top of the crucible), smaller particles are deposited. However, as the stub is systematically brought closer to the particle surface, both smaller and larger particles are deposited on the SEM stub. For example, when the stub is −15 mm from the top of the crucible, approximately 91% of the particles have an area less than 50 μm², whereas at −20 mm, about 85% of the particles are less than 50 μm². Additionally, a considerable percentage of the particles (≈4%) are more than 200 μm² when the stub is −20 mm from the top of the crucible. These results show a change in particle size distribution upon the operating conditions of the EMSBot.

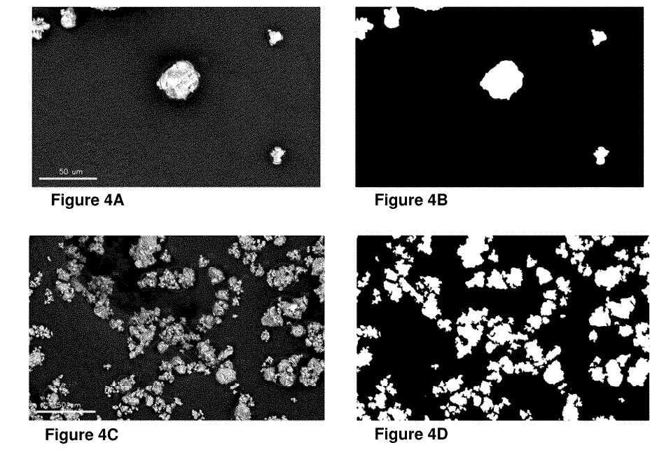

To demonstrate the uniformity of particle dispersion achieved with EMSBot-prepared samples, SEM micrographs of samples prepared using both the EMSBot and manual methods are compared. FIGS. 4A-4D show ball-milled precursor samples of Na₄P₂O₇ and SnO₂, with EMSBot-prepared samples shown in panels FIGS. 4A and 4B, and manually prepared samples in panels FIGS. 4C and 4D. This particular precursor powder system was selected as a test case due to the challenges associated with manual SEM sample preparation and the importance of accurate particle size characterization for achieving the desired target composition.

The SEM images clearly show that EMSBot-prepared samples (FIG. 4A) exhibit a more uniform particle distribution and greater separation between particles, whereas manually prepared samples (FIG. 4C) display significant agglomeration. Binary masked images derived from the SEM micrographs, shown in FIG. 4B (EMSBot) and 4D (manual), further emphasize these differences in particle dispersion. These binary masked images were used to determine the particle size distribution.

Further, to demonstrate the reproducibility of enhanced particle dispersion, wet-mixed precursor samples of Na₄P₂O₇ and SnO₂ prepared using the EMSBot and manual methods were compared. The EMSBot-prepared samples exhibited much better dispersion than manually prepared samples. The decrease in particle agglomeration is also evident in optical images.

Overall, these results demonstrate that well-dispersed SEM stubs, as produced by the EMSBot, enable more reliable particle size analysis by minimizing particle overlap compared to manually prepared stubs.

Another feature of the EMSBot is its ability to prepare samples for both scanning and transmission electron microscopy. For transmission electron microscopy sample preparation, a conventional TEM grid can be used instead of the SEM stub.

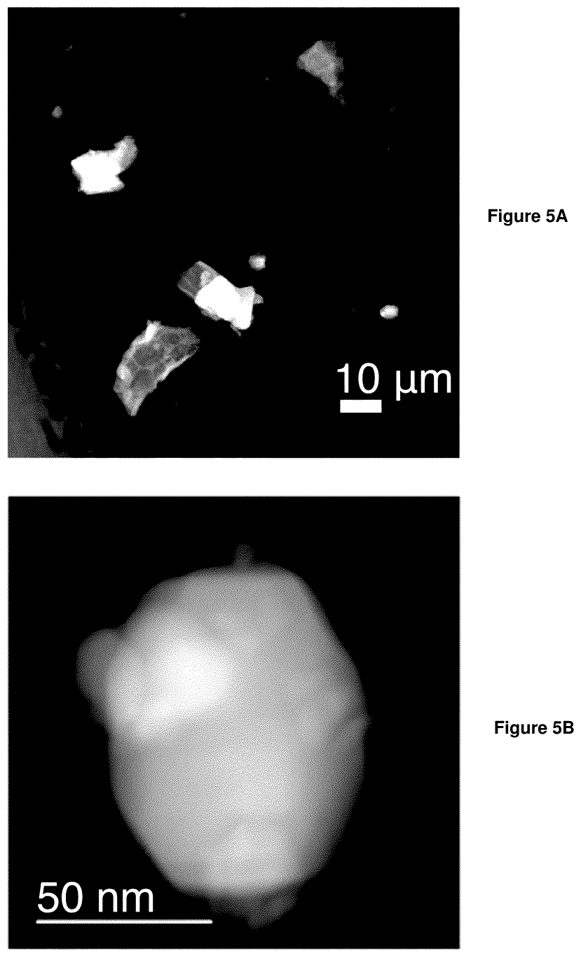

To demonstrate this capability, a TEM sample was prepared from Al(OH)₃ powder using exposure parameters of 10 kV and 10 mA for 5 seconds, with the sample positioned 8 mm below the top of the crucible. A standard 3 mm holey carbon-supported copper (Cu) TEM grid was employed for sample collection. FIG. 5A shows a representative low-magnification scanning transmission electron microscope high-angle annular dark field (STEM-HAADF) micrograph of Al(OH)₃ particles. Well-dispersed electron-transparent particles, approximately 50 nm in diameter, are readily observed on the grid prepared using EMSBot, one example of which is shown in FIG. 5B.

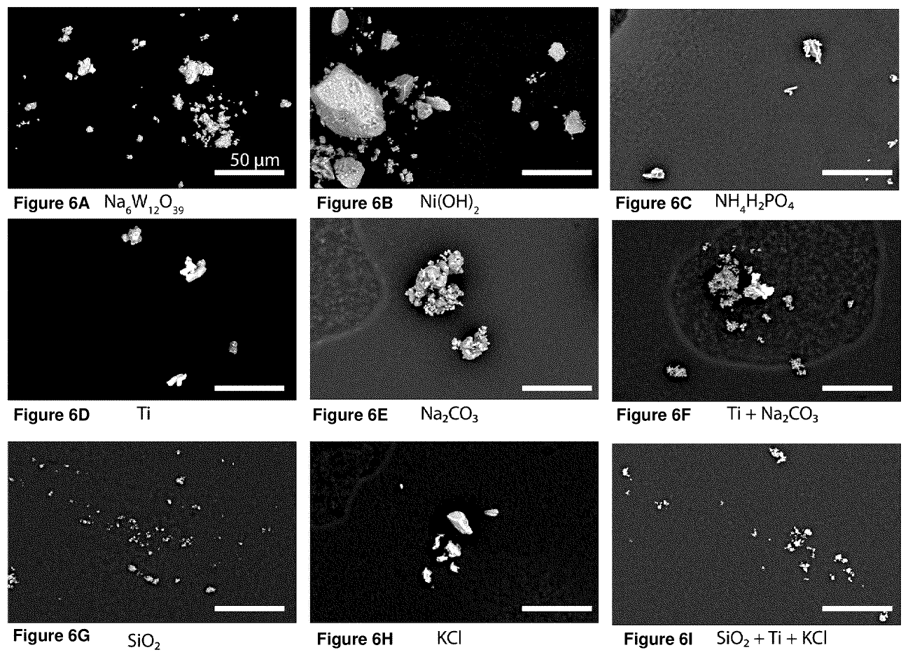

To demonstrate the universality of the EMSBot in preparing powder samples for electron microscopy characterization, SEM samples of various materials were prepared. The SEM micrographs of these samples are shown in FIGS. 6A-6I. Oxide ceramics such as Na₆W₁₂O₃₉ and SiO₂, hydroxides such as Ni(OH)₂, phosphates such as NH₄H₂PO₄, metal particles such as Ti, carbonates such as Na₂CO₃, and chlorides such as KCl were tested. Further, mixtures of particles such as Ti and Na₂CO₃, and SiO₂ with Ti and KCl were tested. In all of these cases, an appreciable amount of well-dispersed particles for SEM characterization was obtained.

### EXAMPLE—EMSBot Discussion

The creation of fully automated SDLs requires systems that are integrated with one another across aspects of experimental procedures. Automated sample preparation has posed a bottleneck in integrating advanced characterization techniques such as electron microscopy into SDLs. The EMSBot is introduced herein, which represents an advancement in the realm of automated electron microscopy powder sample preparation.

An advantage of the EMSBot is its modular architecture, which enhances the adaptability of the system to various research environments while aligning with the objectives of incremental integration into mature autonomous labs. Research groups can incorporate the EMSBot without extensive changes to their current systems, minimizing disruption and maximizing resource utilization. This integration is facilitated by a range of carefully engineered features on both the hardware and software fronts.

On the backend, the EMSBot employs the User Datagram Protocol (UDP) to provide a robust programmatic interface for machine control. The UDP server enables bi-directional communication between the client, such as a user or an autonomous lab orchestration system, and the EMSBot server. Given that most workflow orchestration systems utilize Python as the backend, researchers can implement a UDP client to establish communication with the EMSBot, regardless of their operating system. UDP's platform independence, running over ethernet, ensures cross-platform compatibility. Further, the EMSBot web server backend is built using widely adopted frameworks that can be deployed across diverse environments. To further streamline integration, the EMSBot offers a set of clearly defined and well-documented APIs for controlling and monitoring the instrument. These APIs are documented in the source code, enabling research groups to rapidly develop adapter layers that integrate the EMSBot with their workflow management and data storage systems. This approach mirrors the integration of commercial equipment where adapters leverage standardized interfaces. Given the diversity of autonomous research platforms, including autonomous lab operating systems, it is not feasible to provide ready-to-use integration code for every system. Instead, the EMSBot's clean and accessible API allows users to readily adapt the integration to their specific workflows.

The hardware design of the EMSBot also supports modularity and ease of integration. The sample input position, SEM stub holder, and TEM grid are all placed on the bed to ensure collision-free access, particularly in coordination with mechanical manipulators such as robot arms. The stepper motor on the bed can move samples linearly with high accuracy (well below 1 mm) in the x-y plane, positioning them precisely where a manipulator can safely and efficiently transfer them to other systems. Additionally, the slotted aluminum extrusion frame allows the EMSBot to be securely mounted such as against an optical breadboard, ensuring consistent positioning over time.

The graphical user interface (GUI) and full Python backend serve as significant assets in this integration process, lowering the entry barrier for new users. Further, the flexible hardware design anticipates the straightforward addition of standard powder sample preparation practices, such as mechanical grinding of particles, ensuring that the EMSBot can evolve alongside the needs of the research community.

Statistical analyses conducted during experiments revealed insights into the change in the particle size distribution facilitated by the EMSBot. The distribution of particle sizes demonstrates that when the stub is positioned further away from the powder surface, primarily smaller particles are dispensed onto it, while a closer stub position allows both larger and smaller particles to be collected. This change in particle size distribution capability opens new avenues for electron microscopy sample preparation. For instance, when preparing samples for transmission electron microscopy (TEM) or techniques requiring strict particle size criteria, this feature could ensure that only appropriately sized particles are transferred to the specimen grids. However, further investigations need to be conducted to optimize the exposition criteria for samples with different chemistries and particle sizes to achieve particle size selectivity using the EMSBot.

Samples prepared by the EMSBot can be analyzed using SEM-EDS to assess morphology and composition. Additionally, TEM grids produced with the EMSBot are suitable for a wide range of advanced electron microscopy techniques, including electron diffraction. While particle size does not determine material chemistry, it plays a crucial role in characterization. Specifically, TEM measurements often require small particles (typically <150 nm) to achieve electron transparency, whereas SEM measurements generally necessitate larger particles (>200 nm) due to spatial resolution constraints. By enabling the preparation of appropriately sized powder samples, the EMSBot effectively facilitates and supports downstream characterization using both SEM and TEM for advanced analyses.

Samples prepared using the EMSBot show a uniform particle dispersion and significantly reduced particle agglomeration compared to the samples prepared manually (FIGS. 4A-4D). It is hypothesized that this uniformity is a result of the electrostatic repulsion between the charged particles during the transfer from the crucible to the SEM stub. Given that techniques such as micro electron diffraction (microED) need a minimum separation of particles, typically greater than 1 μm for effective structure determination, the EMSBot's precision in controlling the quantity and size of particles could be invaluable in structure determination for new material systems. Further, achieving phase purity of certain target phases can depend on the particle sizes of the precursors. Uniform dispersion and reduced agglomeration of particles facilitate more accurate characterization of particle size by improving the reliability of particle-finding algorithms. Descriptors such as particle size, and its influence on achieving the target phase, can lead to better optimization of material synthesis recipes and provide insights into synthesis science.

Another advantage of the EMSBot is the solvent free approach to TEM sample preparation. Traditional drop-casting methods for TEM sample preparation often involve a solvent-based method for dispersing smaller particles in a dilute concentration and drop casting a small amount of the dispersed solution onto a TEM grid. However, in an SDL with a target of accelerated development of new materials, the stability of the synthesized material against solvents would be unknown, making TEM sample preparation challenging. While drop casting is a preferred pathway for many samples, it can also introduce artifacts for nanoparticles tending to agglomerate and dry up at the edge of the drop, leading to “coffee ring” effects. The EMSBot overcomes these challenges by using static electricity for TEM sample preparation and provides an alternative solvent-free TEM sample preparation method for the SDL ecosystem.

Further, the results demonstrate that the EMSBot is effective across a broad range of material compositions, including oxides, hydroxides, halides, and pure metals, rendering the system material-agnostic for electron microscopy sample preparation (FIGS. 6A-6I). However, there are limitations when working with materials that are highly hygroscopic or exhibit strong adhesion to the synthesis crucible, resulting in specimens that no longer remain in powder form. Notably, these limitations are similar to those encountered with manually prepared samples.

Finally, the EMSBot is engineered to enable the preparation of both SEM and TEM samples within a single unit. While the integration of benchtop SEMs into self-driving laboratory (SDL) workflows has enhanced capabilities for composition and topography analysis, advanced characterization, such as electron diffraction from transmission electron microscopes, remains indispensable for new material discovery. However, due to time and cost constraints, it is not feasible to analyze every sample using TEM. To address this, SDLs that can automatically flag promising novel material systems for further investigation are possible, with the EMSBot automating the preparation of TEM specimens. This streamlines advanced characterization and fosters more efficient exploration of material properties.

### CONCLUSION

Further details regarding the embodiments described herein can be found in David Milsted et al., “Automated electron microscopy sample preparation system,” Digital Discovery, 2025, 4, 2244, which is hereby incorporated by reference.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

What is claimed is:

1. A system comprising:
a first sample holder tray operable to hold electron microscopy (EM) sample holders;
a sample holder handling apparatus including a sample holder mechanism;
a sample exposing apparatus, the sample exposing apparatus including:
a platform;
an electrode; and
a high voltage power supply, the high voltage power supply operable to apply a voltage to the electrode and an EM sample holder or a second electrode positioned proximate the EM sample holder, and the voltage operable to attract a powder sample disposed on the platform to the EM sample holder; and
the sample holder handling apparatus operable to transfer the EM sample holder between the first sample holder tray and the sample exposing apparatus.

2. The system of claim 1, wherein the sample holder mechanism comprises a tweezer-like mechanism operable to hold an EM sample holder.

3. The system of claim 1, wherein the sample holder mechanism comprises:
a vacuum pump; and
an EM needle, wherein the EM needle comprises a hollow cylinder operable to hold an EM sample holder when a vacuum is applied to the hollow cylinder with the vacuum pump.

4. The system of claim 1, wherein the electrode is on an upper surface of the platform.

5. The system of claim 1, further comprising:
a sensor operable to sense when the sample holder handling apparatus picks up the EM sample holder.

6. The system of claim 5, wherein the sensor comprises a laser sensor.

7. The system of claim 1, wherein the platform comprises a flat surface.

8. The system of claim 1, wherein the platform comprises an electrically insulating material.

9. The system of claim 1, wherein the platform comprises polypropylene.

10. The system of claim 1, wherein the platform comprises polypropylene, and wherein the polypropylene is about 3 millimeters to 5 millimeters thick.

11. The system of claim 1, wherein the EM sample holders are scanning electron microscopy (SEM) stubs.

12. The system of claim 11, wherein the voltage is applied to the electrode and the SEM stub.

13. The system of claim 11, wherein the voltage is applied to the electrode and the SEM stub, and wherein the voltage is about 100 V to 50 kV.

14. The system of claim 11, wherein a distance between the platform and the SEM stub when the voltage is applied to the electrode and the SEM stub is about 1 millimeter to 50 millimeters.

15. The system of claim 1, wherein the EM sample holders are transmission electron microscopy (TEM) grids.

16. The system of claim 15, wherein the voltage is applied to the electrode and the second electrode positioned proximate the TEM grid, and wherein the TEM grid is positioned between the platform and the second electrode.

17. The system of claim 15, wherein the voltage is applied to the electrode and the second electrode positioned proximate the TEM grid, and wherein the voltage is about 100 V to 50 kV.

18. The system of claim 15 wherein a distance between the platform and the TEM grid when the voltage is applied to the electrode and the second electrode is about 1 millimeter to 50 millimeters.

19. The system of claim 15, wherein the voltage is applied to the electrode and the second electrode positioned proximate the TEM grid, wherein the TEM grid is positioned between the platform and the second electrode, and wherein the TEM grid is positioned at a distance from the second electrode such that the TEM grid is electrically isolated from the second electrode when the voltage is applied to the electrode and the second electrode.

20. A system comprising:
a first sample holder tray operable to hold scanning electron microscopy (SEM) stubs;
a second sample holder tray operable to hold transmission electron microscopy (TEM) grids;
a sample holder handling apparatus including:
a vacuum pump;
a SEM needle, the SEM needle comprising a first hollow cylinder operable to hold a SEM stub when a vacuum is applied to the first hollow cylinder with the vacuum pump; and
a TEM needle, the TEM needle comprising a second hollow cylinder operable to hold a TEM grid when a vacuum is applied to the second hollow cylinder with the vacuum pump; and
a sample exposing apparatus, the sample exposing apparatus including:
a platform comprising a flat surface;
an electrode; and
a high voltage power supply, the high voltage power supply operable to apply a voltage to the electrode and the SEM stub or the electrode and a second electrode positioned proximate the TEM grid, the voltage operable to attract a powder sample disposed on the platform to the SEM stub or the TEM grid;
the sample holder handling apparatus operable to transfer the SEM stub or the TEM grid to the first sample holder tray or the second sample holder tray, respectively, and the sample exposing apparatus.
